(19) United States
(12) Patent Application Publication
(10) Pub. No.: US 2018/0051389 A1
(43) Pub. Date: Feb. 22, 2018

(54) APPARATUSES AND METHODS FOR PRODUCING THIN CRYSTAL FIBERS USING LASER HEATING PEDESTAL GROWTH

(71) Applicant: Shasta Crystals, Inc., San Francisco, CA (US)

(72) Inventors: Gisele Maxwell, San Francisco, CA (US); Bennett Ponting, Berkeley, CA (US)

(73) Assignee: Shasta Crystals, Inc., San Francisco, CA (US)

(21) Appl. No.: 15/554,703

(22) PCT Filed: Jun. 12, 2015
(86) PCT No.: PCT/US15/35684

§ 371 Date: Aug. 30, 2017

Related U.S. Application Data
(60) Provisional application No. 62/138,301, filed on Mar. 25, 2015.

(51) Int. Cl. C30B 15/16; C30B 29/24; C30B 29/60; C03B 37/01; G02B 6/10; C03C 13/04

(52) U.S. Cl. CPC C30B 15/16; C30B 29/24; C03C 13/041; C03B 37/011; G02B 6/102; C30B 29/60

(57) ABSTRACT

Disclosed are apparatuses and methods for growing thin crystal fibers via optical heating. The apparatuses may include and the methods may employ a source of optical energy for heating a source material to form a molten zone of melted source material, an upper fiber guide for pulling a growing crystal fiber along a defined translational axis away from the molten zone, and a lower feed guide for pushing additional source material along a defined translational axis towards the molten zone. For certain such apparatuses and the methods that employ them, the lower feed guide's translational axis and upper fiber guide's translational axis are substantially aligned vertically and axially so as to horizontally locate the source material in the path of optical energy emitted from the optical energy source, in some cases to within a horizontal tolerance of about 5 μm.

### CROSS-REFERENCE TO RELATED APPLICATIONS

This disclosure claims priority to U.S. Provisional Patent Application No. 62/138,301 (Attorney Docket No. SCRSP001PUS), filed Mar. 25, 2015, entitled “APPARATUSES AND METHODS FOR PRODUCING THIN CRYSTAL FIBERS USING LASER HEATING PEDESTAL GROWTH,” which is hereby incorporated by reference.

### BACKGROUND

Fiber lasers are advantageous over their traditional counterparts due to their ability to implement a very long laser gain medium (and thereby produce very high power laser radiation) in what amounts to a very compact geometry. FIG. 1 schematically illustrates the cross-section of a simple fiber laser design as viewed down the central axis of the fiber. The figure shows that the basic fiber 100 consists of a core 110 of doped lasing material, surrounded by an outer cladding 120 which acts as a waveguide and also provides the reflections necessary to set up an optical resonator. In conventional fiber lasers, the core 110 of the laser fiber is made from doped glass; the use of a glass material, however, compromises many of the advantages often associated with the use of a crystalline laser gain medium as typically employed in an ordinary (non-fiber) laser design.

### SUMMARY

Disclosed herein are apparatuses for growing thin crystal fibers via optical heating. The apparatuses may include a source of optical energy for heating a source material to form a molten zone of melted source material, an upper fiber guide for pulling a growing crystal fiber along a defined translational axis away from the molten zone (thereby also withdrawing un-crystalline melted source material connected with the crystal fiber away from the molten zone so that melted source material may cool, crystalize, and add to the growing crystal fiber), and a lower feed guide for pushing additional source material along a defined translational axis towards the molten zone. In certain such embodiments, the lower feed guide's translational axis is aligned so as to horizontally locate the source material in the path of optical energy emitted from the optical energy source. In certain such embodiments, the upper fiber guide's translational axis is aligned so as to horizontally locate the source material in the path of optical energy emitted from the optical energy source. In certain such embodiments, the lower feed guide's translational axis and upper fiber guide's translational axis are substantially aligned vertically and axially so as to horizontally locate the source material in the path of optical energy emitted from the optical energy source. In some embodiments, the upper fiber guide is configured to pull the crystal fiber away from the molten zone at a translational rate greater than the translational rate at which the lower feed guide is configured to push the source material towards the molten zone.

In some embodiments, the apparatuses may further include a diameter-control feedback system. The diameter-control feedback system may include a fiber diameter measurement module configured to measure the diameter of the growing crystal fiber, and a controller configured to adjust the translational rate at which the lower feed guide pushes the source material in response to signals received from the fiber diameter measurement system, so as to keep the diameter of the growing crystal fiber approximately constant. In certain such embodiments, the fiber diameter measurement module includes a probe laser configured to irradiate the growing crystal fiber with laser radiation, and a light detector configured to measure one or more interference fringes produced by the interaction of said laser radiation with the growing crystal fiber.

Depending on the embodiment, the lower feed guide may include a lower guide tube having an interior that defines the translational axis along which the lower feed guide pushes source material towards the molten zone, a guide block having a groove, and a feed belt. Depending on the embodiment, the upper fiber guide may have an interior that defines the translational axis along which the upper fiber guide pulls the growing crystal fiber away from the molten zone, and may include a pair of guide pads configured to exert horizontal pressure on the crystal fiber from two sides so as to further stabilize its horizontal location as it is pulled away from the molten zone, and it may further include a spooling drum configured to pull the crystal fiber through the pair of guide pads and away from the molten zone by rotating.

Also disclosed herein are methods for growing a thin crystal fiber via optical heating. The methods may include heating a source material with optical energy to form a molten zone of melted source material, pulling a growing crystal fiber along a translational axis defined by a fiber guide away from the molten zone (thereby also withdrawing un-crystalline melted source material connected with the crystal fiber away from the molten zone so that the melted source material may cool, crystalize, and add to the growing crystal fiber), and pushing additional source material along a translational axis defined by a feed guide towards the molten zone. In certain such embodiments, the translational axis defined by the feed guide and the translational axis defined by the fiber guide are substantially aligned vertically and axially so as to horizontally locate the source material in the path of optical energy within a horizontal tolerance of about 5 μm.

In some embodiment methods, the crystal fiber is pulled away from the molten zone at a translational rate greater than the translational rate at which the source material is pushed towards the molten zone, and in certain such embodiments, the translational rate at which the crystal fiber is pulled is between 2 and 25 times the translational rate at which the source material is pushed. In some embodiments, the thin crystal fiber growing methods may further include measuring the diameter of the growing crystal fiber, and adjusting the translational rate at which the lower feed guide pushes the source material, so as to keep the diameter of the growing crystal fiber approximately constant. Some embodiment methods may further include varying the ratio of translational pull to translational push by a rate of between about 0.1% and 10% per cm of drawn crystal fiber over some portion of the crystal fiber's length as it is grown.

In some embodiment methods, the source material pushed towards the molten zone is a rod of polycrystalline material, such as doped polycrystalline YAG, whereas in some embodiment methods, the source material pushed towards the molten zone is a crystal fiber grown in a prior operation of optical heating, and the diameter of the grown crystal fiber is less than the diameter of the source crystal fiber by a factor of between about 1.5 and 5.

In some embodiments, the crystal fibers which may be produced with the foregoing methods and/or apparatuses may have diameters of 40 μm or less, and lengths of 30 cm or more, and, in certain embodiments, they may be composed of doped crystalline YAG.

### BRIEF DESCRIPTION OF THE DRAWINGS

FIG. 1 is a cross-sectional view down the axis of a laser fiber having a core of doped lasing material surrounded by an outer cladding.

FIG. 2 is an overall schematic of a laser heating pedestal growth (LHPG) fiber crystal production apparatus consistent with various embodiments disclosed herein.

FIG. 3A is a schematic of the initiation phase of an LHPG process.

FIG. 3B is a schematic of the continuous fiber growth phase of an LHPG process.

FIG. 4 is a close-up schematic view of the lower feed guide component of a fiber crystal production apparatus consistent with various embodiments disclosed herein.

FIG. 5 is a close-up schematic view of the upper fiber guide component of a fiber crystal production apparatus consistent with various embodiments disclosed herein.

FIG. 6 is a close-up schematic view of the optical energy source component of a fiber crystal production apparatus consistent with various embodiments disclosed herein.

FIG. 7 is a comparison plot of lengthwise variations in diameter for a crystal fiber grown using a closed-loop diameter-control feedback system, versus a crystal fiber grown without using a diameter-control feedback system.

### DETAILED DESCRIPTION

In the following description, numerous specific details are set forth in order to provide a thorough understanding of the present invention. However, the present invention may be practiced without some or all of these specific details. In other instances, well known process operations or hardware have not been described in detail so as to not unnecessarily obscure the inventive aspects of the present work. While the invention will be described in conjunction with specific detailed embodiments, it is to be understood that these specific detailed embodiments are not intended to limit the scope of the inventive concepts disclosed herein.

### INTRODUCTION

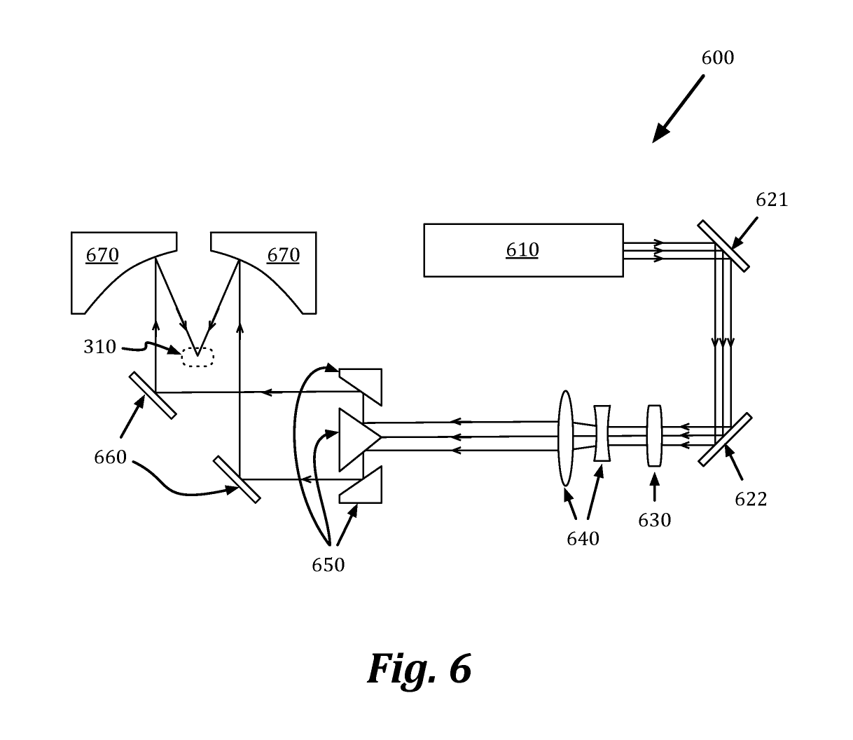

Single crystal fibers can be seen as an intermediate between laser crystals and doped glass fibers. In some embodiments, they may possess both the capability of serving as efficient wave guides for laser light, as well as matching the efficiencies generally found in bulk crystals. This combination makes them candidates for high-power laser and fiber laser applications. Thus, while it is true that the core lasing material (see FIG. 6A) in a conventional fiber laser design is made from doped glass, disclosed herein are thin, doped single-crystal fibers and LHPG-based methods (and apparatuses) for producing such thin crystal fibers which are suitable for use as the core lasing material in fiber laser applications.

For example, single-crystal fibers of yttrium aluminum garnet (YAG, Y₃Al₅O₁₂) provide a potential pathway to fiber lasers with higher output power. Compared with amorphous silica glass fibers, single crystal YAG fibers offer higher thermal conductivity, higher stimulated Brillouin scattering thresholds, higher melting temperatures, and higher doping concentrations, as well as excellent environmental stability. Table 1 compares the thermal, physical, and optical properties of amorphous silica glass fibers and single crystal YAG fibers.

TABLE I

| | | | | | Rare Earth | Refractive Index | Brillouin |
|---|---|---|---|---|---|---|---|
| | | Thermal | | Theoretical | Dopant | Change of Core | Gain |
| | T_{g} or | Conductivity | Hardness | Strength | Concentration | with Temp | Coefficient |
| | Tₘ | (W/m/K) | (kg/mm²) | (GPa) | (%) | (K⁻¹) | (m/W) |
| Silica Glass | ~1000 | ~1 | 500 | 14.6 | ≦1 | 11.8 × 10⁻⁶ | 5 × 10⁻¹¹ |
| | (T_{g}) | | | | | | |
| YAG Single | 1950 | ~10 | 1350 | 56.0 | ~10 | 9 × 10⁻⁶ | <0.01 × 10⁻¹¹ |
| Crystal | (Tₘ) | | | | | | |
| Advantage of | 2x | 10x | >2x | >2x | 10x | 1.3 | >100x |
| YAG Crystals | | | | | | | |
| Over Glass | | | | | | | |

LHPG Apparatuses and Methods

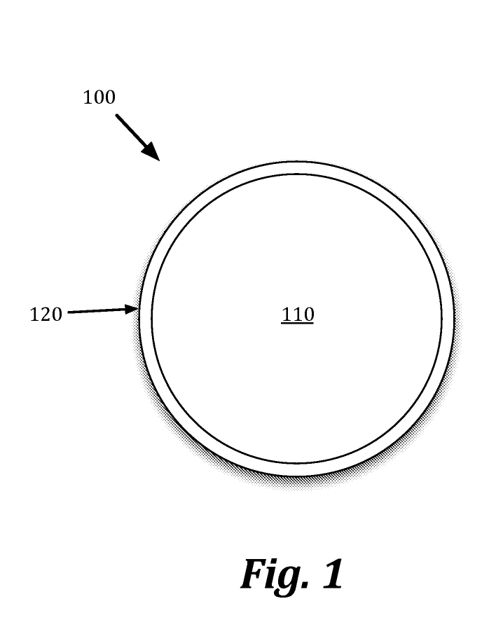

Disclosed herein are various fiber crystal production apparatuses and associated methodologies which employ the laser heating pedestal growth (LHPG) technique to produce thin crystal fibers of various materials. For details on the technique as it was originally pioneered, see, e.g., M. M. Fejer, J. L. Nightingale, G. A. Magel and R. L. Byer, “Laser-Heated Miniature Pedestal Growth Apparatus for Single-Crystal Optical Fibers,” Rev. Sci. Instrum. 55, 1791-17 (1984), which is hereby incorporated by reference in its entirety for all purposes. Traditionally, crystal fibers produced by such methods have been limited to having diameters of on the order of about 100 μm or greater. Disclosed herein are improved LHPG apparatuses and associated methodologies capable of producing thin crystal optical fibers with diameters of about 100 μm or less (or even about 90 or 80 or 70 or 60 or 50 or 40 or 30 μm or less, depending on the embodiment). Moreover, these thin crystal fibers (produced by these apparatuses and associated methodologies) may have lengths of about 20 cm or more (or even about 30 or 40 or 50 or 60 or 70 or 80 or 90 or 100 cm or more, depending on the embodiment). As stated, such thin crystal fibers may be used for various applications such as, for instance, serving as the waveguide core in a fiber laser (as shown in FIG. 1).

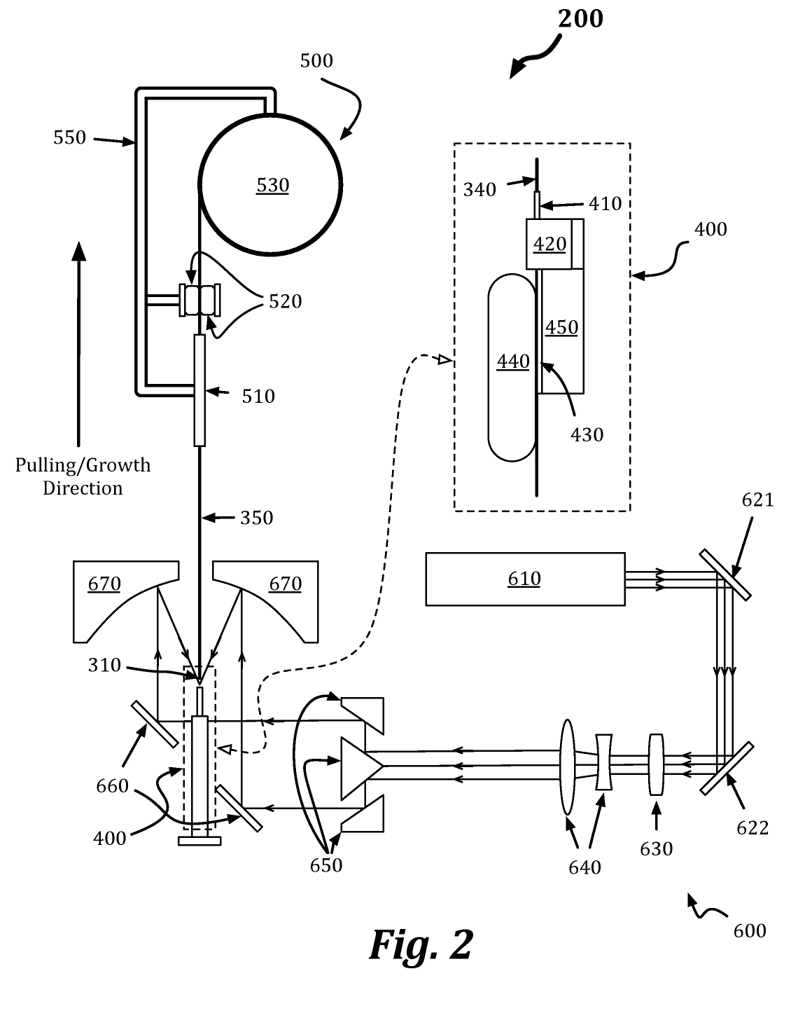

FIG. 2 displays an overall schematic of such an LHPG fiber crystal production apparatus consistent with various embodiments described herein. As shown in the figure, the apparatus 200 comprises lower feed guide 400, upper fiber guide 500, and a source of optical energy 600 including laser source 610 (e.g. an infrared CO₂ laser of 10.6 μm wavelength, typically having a power range of between about 1 and 100 W) and various optical components 620 et seq. for guiding the laser emission from its source 610 to the region where the crystal fiber is formed through optical heating. As also shown in the figure, this region of optical heating and crystal formation is referred to as molten zone 310 and it is located between the lower feed guide 400 and the upper fiber guide 500—in this embodiment, just slightly vertically above the lower feed guide.

In an operation of growing a thin crystal fiber, the apparatus 200 operates by feeding a fiber or rod of source material 340 (hereinafter referred to as just source material) from below (see the displayed detail of lower feed guide 400) into the region of space referred to as molten zone 310 in FIG. 1A. The source material 340 may be a pressed and/or sintered and/or cut pellet or rod of raw polycrystalline stock material, or it may be a crystal fiber grown in a prior LHPG operation—here being processed again to make the crystal fiber thinner still, or to improve its crystal structure through another round of melting and crystallization, or typically to achieve both goals. In the former case, for example, the source material may be a doped polycrystalline YAG stock of about 1 inch long and 1 mm square. For such source material the CO₂ laser may be operated at a power level of between about 10 and 15 W, though it should be understood that different thicknesses of feed stock may require more or less power for sufficient heating to occur, and moreover, that subsequent fiber growth operations on a previously grown fiber, since thinner, would typically require correspondingly less laser power. (For example, in a series of LHPG operations for sequentially reducing the fiber diameter, the final reduction may require less than 1 watt of power.)

Once within the molten zone, the source material 340 is heated with optical energy from source 600 to the extent that it is melted into a molten state. The molten material is then pulled upwards and withdrawn from the molten zone whereby it cools, crystalize, and add to the growing crystal fiber 350. Generally, this process takes place continuously—i.e., the source material 340 is moved in continuous fashion into the molten zone 310 by being pushed from below with lower feed guide 400 (towards the molten zone), while simultaneously a growing thin crystal fiber 350 is pulled out of and away from the molten zone from above by upper fiber guide 500.

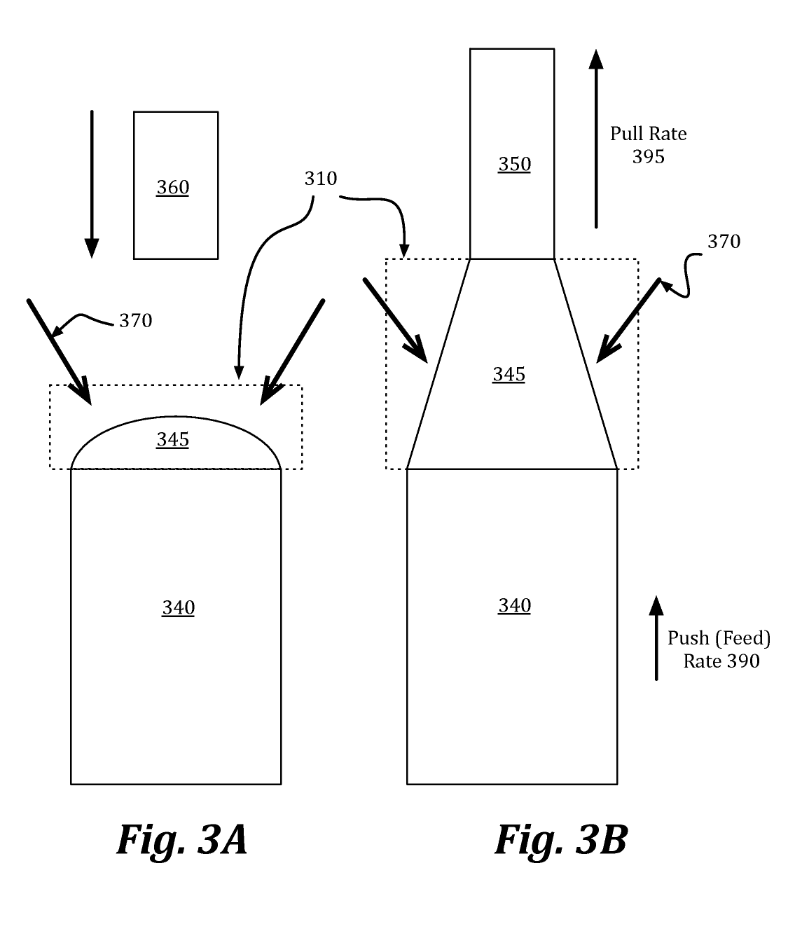

However, before the crystal fiber may be drawn continuously from the melt, the LHPG process must be initiated. As illustrated in FIG. 3A, this is done by positioning source material 340 (e.g., a raw polycrystalline rod or pellet, crystal fiber formed from a prior LHPG operation, etc.) in the path of laser beam 370, focused down upon a tip of such material to melt it forming melt 345 and, accordingly, the aforementioned molten zone 310. As further shown in FIG. 3A, a seed crystal 360 is then lowered into the melt 345—e.g., by attaching said seed crystal to a string and mechanically lowering it—and when it is subsequently withdrawn/pulled from the melt, as shown in FIG. 3B, the melted source material adhered/connected to it is removed from the vicinity of the focused laser whereby it may begin to cool and crystallize to form the crystal fiber 350. The crystal fiber may then be grown continuously as it is drawn from the melt 345, so long as the molten zone is sufficiently fed from below with sufficient additional source material as just described. Note that by choosing the orientation of the seed crystal 360 as it is lowered into and withdrawn/pulled from the melt 345, a crystal fiber 350 having substantially the same crystal orientation as the seed crystal 360 may be produced. Also, note that laser beam 370 in FIGS. 3A and 3B is depicted in schematic cross-section, so although two arrows appear in the figures to indicate the direction of laser propagation into the melt, it should be understood that the two arrows could represent two laser beams, or they could more preferably represent a cross-section of a single conical beam such as that which would be produced by those optical elements shown in FIG. 2 (described in detail below with respect to FIG. 6)—specifically, reflaxicon 650, elliptical turning mirror 660, and parabolic focusing mirror 670.

While the foregoing LHPG-based technique may be used to convert polycrystalline source material into a crystal fiber (e.g., a single-crystal fiber), the process may also work to achieve a reduction in diameter of the fiber relative to the diameter of the source material (or a further diameter reduction if a previously grown crystal fiber is used as the source material as indicated below). As illustrated in FIG. 3B, this may be done by making the translational rate 395 at which the crystal fiber 350 is pulled away from the molten zone 310 from above (by upper fiber guide 500) greater than the translational rate 390 at which the raw source material 340 is pushed towards the molten zone from below (by lower feed guide 400). Conceptually, this is akin to the molten source material being stretched or drawn out as it is cools and crystallizes to form the crystal fiber. Accordingly, the diameter of the crystal fiber exiting the molten zone is generally less than the diameter of the source material entering the molten zone by some diameter reduction factor. Depending on the embodiment, fiber diameters may be reduced by factors of between about 1.5 and 5, or more particularly between about 2 and 4, or yet more particularly between about 2 and 3. Correspondingly, the translational rate at which the upper fiber guide is configured to pull the crystal fiber from above may be between about 2 and 25 times the translational rate at which the lower feed guide is configured to push the source material from below, or more particularly between about 4 and 16 times, or still more particularly between about 4 and 9 times.

Note that in practice a fiber of “constant” thickness will still exhibit some variation in diameter along its length. Accordingly, for purposes of this disclosure, a fiber's diameter or thickness is hereby defined as its radially averaged thickness (e.g., the fiber may be slightly ellipsoidal) averaged over a portion of the fiber's length. Generally, and unless indicated otherwise, said portion of the fiber's length being averaged over is a region of the fiber produced via the LHPG process having stabilized. Furthermore, unless indicated otherwise, this length being averaged over is assumed to be 2 cm. Using these definitions, a constant diameter fiber is one whose average thickness deviates by about 2% or less over the portion of the fiber's length said to have a constant diameter.

Moreover, the foregoing process may be repeated sequentially on the same physical material to form fibers of progressively narrower diameter and, in some embodiments, progressively higher quality (more uniform) crystal structure. Thus, for instance, if the diameter reduction factor is about 3, to get to a sub-100 μm fiber starting from a 1 mm YAG source feed rod, a 3 stage diameter reduction process may be performed, e.g.: a first stage going from about 1000 μm down to about 350 μm; a second stage going from about 350 μm to about 120 μm; and finally a third stage effecting a diameter reduction from about 120 μm to about 40 μm. It is noted that these stages may be conducted sequentially using a single LHPG apparatus by re-feeding a formed crystal fiber from a prior stage back into the apparatus to serve as source material for the next stage, or successive diameter reductions may be performed via an apparatus having multiple LHPG stations each individually dedicated to a particular stage of the complete diameter reduction process.

Depending on the embodiment, the rate at which a crystal fiber may be grown in such processes is typically, for example, between about 1 and 2 mm/min for the growth of 500-1000 μm diameter crystals, and, for example, between about 3 and 5 mm/min for the growth of 30-120 μm diameter crystals (starting with a source material of appropriate diameter). Depending on the embodiment, fibers may be grown to lengths of between about 10 to 90 cm, in this manner. The crystal fibers become more flexible as their diameter is reduced with fibers of about 100 μm diameter having a bend radius of about 1 cm and thinner fibers having correspondingly tighter bending radii. Thus, the foregoing LHPG-based technique may be used to grow long, flexible, crystal fibers. It is to be noted, furthermore, that the foregoing techniques may be performed at ambient temperate and pressure conditions to produce such fibers.

In addition to setting the relative translational rates at which the crystal fiber is pulled from above versus the source material pushed from below to effect a diameter reduction, in certain embodiments, it is feasible to adjust the relative translational rates of push and pull during the crystal fiber formation process. This might be done as part of a closed-loop diameter-control feedback system designed to ensure that the fiber being produced has a consistently uniform diameter over substantially its entire length (or over a particular portion of its length). Such a closed-loop diameter-control feedback system may operate by measuring the diameter of the fiber as it is produced and automatically making process adjustments accordingly—further details are provided below.

In other embodiments, adjusting relative pull/push translational rates might be done in order to intentionally vary the diameter of the crystal fiber being produced to achieve some predetermined radial profile appropriate for the crystal fiber's use in particular applications. For example, in some applications, it may be advantageous to produce a fiber having a radially flared end, or having each end radially flared, or a fiber having a constantly tapering diameter along some portion of its length. In principle, controlling the relative pull and push rates may be done by adjusting the push rate, adjusting the pull rate, or adjusting both. In practice, it has been found effective to adjust only the push rate while keeping the pull rate constant (both in order to produce a constant diameter crystal fiber via a closed-loop diameter-control feedback system, and also in scenarios where it is desirable to generate a variable diameter crystal fiber of some predetermined profile).

In addition to producing a fiber with a flared end (and/or having each end flared, and/or having a constant tapering region), generally, any appropriate function may be used (with this technique) to define (and generate) a desired variation in diameter down the length of the fiber (or down some portion of it). As stated above, to produce a thin fiber from a thicker source stock, the fiber is drawn out by pulling it from the molten zone at a translational rate which is greater than the translational rate at which it is pushed into the molten zone. Thus, to change the fiber's diameter as it is produced in order to achieve a certain diameter variation along its length, the ratio of translational pull to translational push may be correspondingly adjusted as the fiber is drawn. While this ratio is varied, there will be generated a corresponding variation in the fiber's diameter; likewise, once the ratio is again held fixed, the corresponding portion of the fiber's diameter will again be generated having a constant diameter along its length (albeit possibly a different diameter than that which was initially produced; i.e., if the pull/push ratio is different than what was used initially). Depending on the embodiment, the rate at which the pull/push ratio may be adjusted/varied/changed per unit length of drawn fiber to achieve a certain diameter variation (taper) in the drawn fiber may be between about 0.1% and 75% per cm of drawn fiber, or more particularly between about 0.1% and 50% per cm of drawn fiber, or still more particularly between about 0.1% and 25% per cm of drawn fiber, or even just between about 0.1% and 10% per cm of drawn fiber. It is recognized that the fiber diameter will vary (per unit length) roughly inversely with the square root of the variation in pull/push ratio (per unit length). Depending on the embodiment, the diameter variation per unit length over some portion of the fiber may be between about 0.1% and 10% per cm of drawn fiber, or more particularly between about 1% and 5% per cm of drawn fiber.

A shown in FIG. 2, an apparatus for growing a thin crystal fiber such as those just described (via the laser heating pedestal growth (LHPG) technique) may include a source of optical energy 600 for heating a source material to form a molten zone of melted source material, an upper fiber guide 500 for pulling a growing crystal fiber away from the molten zone, and a lower fiber guide 400 for pushing additional source material towards the molten zone. By pulling the growing crystal away from the molten zone, the upper fiber guide 300 also withdraws un-crystalline melted source material connected with the crystal fiber from the melt (and away from the molten zone) so that melted source material which is withdrawn may cool, crystalize, and add to the growing crystal fiber (as shown in its initial stage in FIG. 1C).

To enable the foregoing precision crystal-growth processes, however, it is important that the crystal-growing apparatus be capable of precisely locating the material being crystalized within the path of optical energy emitted from the optical energy source. To do this, the lower feed guide 400 is configured to precisely define a translational axis along which the source material is pushed towards the molten zone, and likewise, the upper fiber guide 500 is configured to precisely define an analogous translational axis along which the growing crystal fiber is pulled away from the molten zone. The crystal-growing apparatus as a whole then is configured such that these two translational axes are axially aligned with one another, and also typically substantially vertical, as shown in FIG. 2, so that the source material and growing crystal fiber, as well as the melted portion within the molten zone, are all vertically aligned and precisely horizontally located in the optical energy path. In some embodiments, the lower feed guide 400 and upper fiber guide 500 are configured so that they horizontally locate the source material in the path of optical energy (emitted from optical energy source 600) within a horizontal tolerance of about 25 μm, or more particularly within about 10 μm, or yet more particularly within about 5 μm, or even within a horizontal tolerance of only about 2 μm.

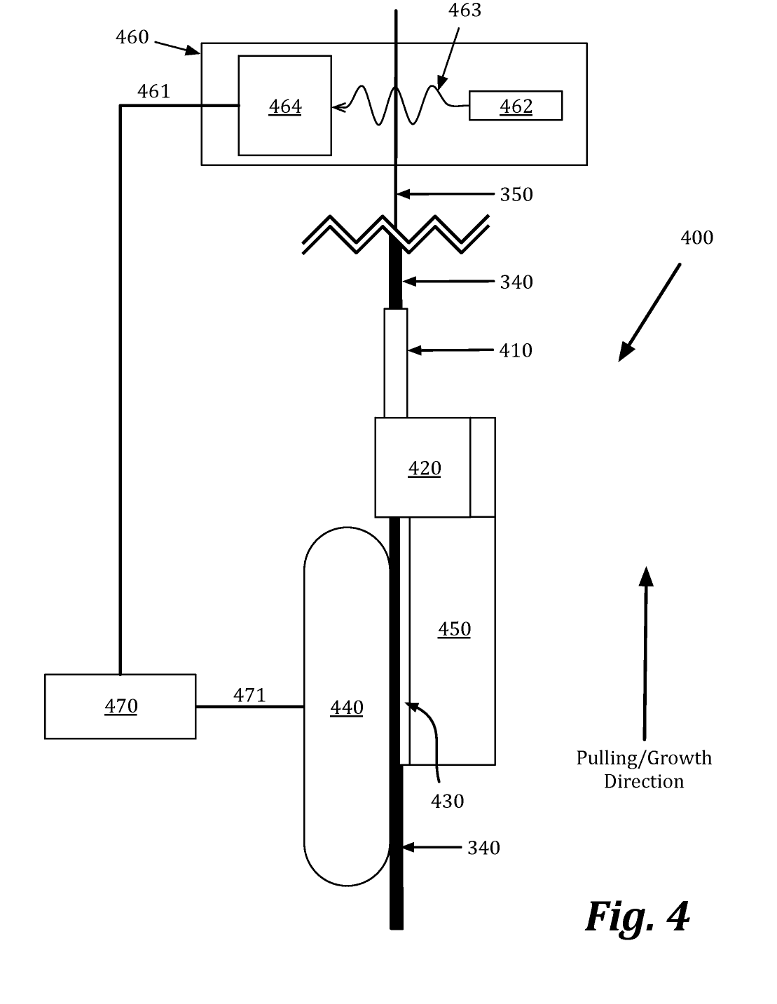

A detailed schematic of one embodiment of a lower feed guide which is configured having a precisely defined translational axis for pushing source material towards the molten zone is shown in FIG. 4. As shown in the figure, lower feed guide 400 may include a lower guide tube 410 and a feed belt 440 which, when it advances, pushes the raw source fiber or rod 340 upwards through the lower guide tube 410 and towards the molten zone. In this particular embodiment, the lower guide tube 410 is supported by guide tube mount 420 which is itself attached to mount structure 450. As shown in the figure, mount structure 450 also has the function of supporting a Teflon guide block 430 (although it should be understood that other appropriate low-friction materials may be substituted such as Delrin, for example) which provides additional support for the raw source material as it is pushed upward towards the molten zone.

Depending on the embodiment, the guide block 430 may have a groove formed in it (not shown from FIG. 4's perspective) within which the raw source resides as it is pushed against by feed belt 440. Thus, the raw source material is sandwiched between feed belt 440 and a groove in guide block 430 (e.g., a Teflon groove) such that when the feed belt advances the raw source material is pushed against and upward through the groove in the guide block and into and through the interior of lower guide tube 410. This sort of design provides for the smooth movement of the raw source material into the molten zone as shown in FIG. 2. Moreover, lower guide tube 410 orients the raw source as it exits the fiber feed guide 400 and thus the interior of the lower guide tube defines the translation axis which aligns the source material as it is pushed toward the molten zone. Lower guide tube 410 may have an interior diameter just slightly larger than the diameter of the raw source material, such that lower guide tube is able to precisely horizontally locate the raw source material as it is pushed towards the molten zone, and in the path of optical energy emitted from the optical energy source 600. Thus, in some embodiments, the interior diameter of the lower guide tube 410 may be selected to be about 15% larger than the diameter of the raw source material being processed or less, or more particularly about 10% larger or less, or yet more particularly about 5% larger or less. Similarly, the radius of the groove in guide block 430 may be selected to be between about 15% larger than the radius of the raw source material being processed or less, or more particularly about 10% larger or less, or yet more particularly about 5% larger or less. Therefore, to produce a suitably thin crystal fiber (for example, in the final diameter reduction step), the inner diameter of the lower guide tube 410 may be chosen to have an interior diameter of about 250 μm or less, or about 200 μm or less, or about 150 μm or less, or still more particularly about 100 μm or less.

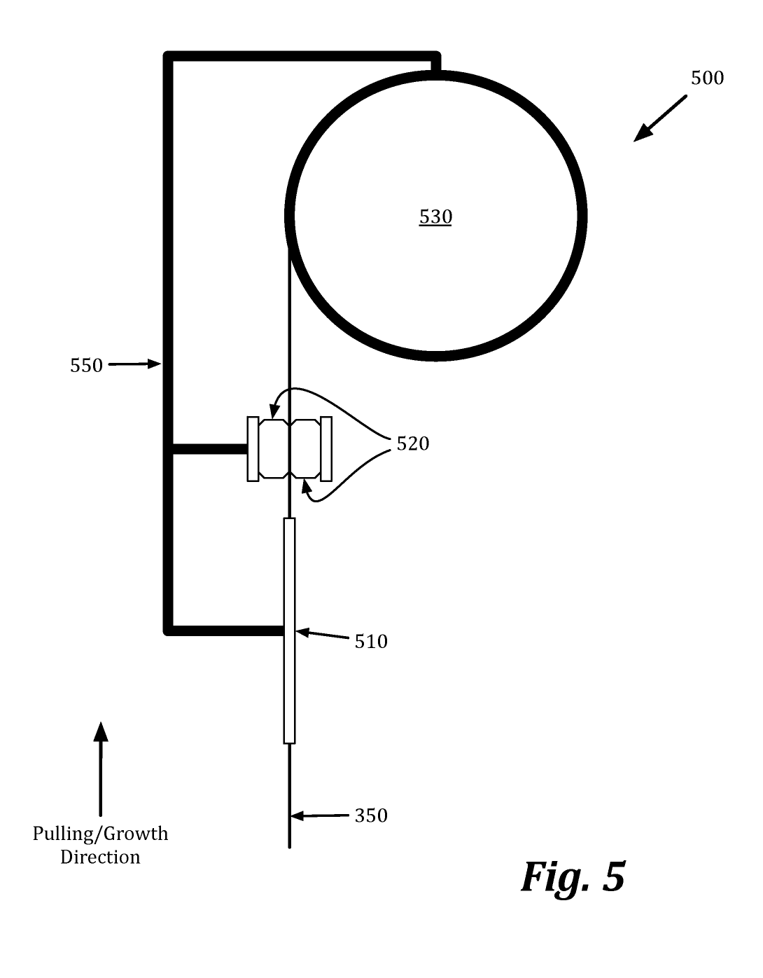

As stated above, to cause a reduction in the diameter of the crystal fiber, the fiber is generally pulled from above with upper fiber guide 500 at a translation rate greater than the translational rate at which it is pushed from below with lower feed guide 400. A detailed schematic of one embodiment of an upper fiber guide which is configured having a precisely defined translational axis for pulling a growing crystal fiber away from the molten zone is shown in FIG. 5. As shown in the figure, upper fiber guide 500 includes a frame 550 which supports an upper guide tube 510, a pair of guide pads 520, and a spooling drum 530.

Upper fiber guide 500 (including upper guide tube 510) may serve the counter-role of lower guide tube 410 in the sense that the upper fiber guide defines the translational axis along which the crystal fiber is pulled away from the molten zone. Thus, the upper fiber guide 500 precisely locates and stabilizes the fiber in the horizontal dimensions while it is pulled upward, however, since the single-crystal fiber exiting the molten zone is generally thinner than crystal fiber or raw polycrystalline source material entering the molten zone, the upper guide tube 510 may, in some embodiments, generally have a proportionally smaller interior diameter relative to that of the lower guide tube 410. For instance, depending on the embodiment, the inner diameter of the upper guide tube 510 may be chosen to have an interior diameter of about 100 μm or less, or more particularly about 75 μm or less, or even only about 50 μm or less. Thus, depending on the embodiment, the interior diameter of the upper guide tube 510 may be selected to be about 10% larger than the diameter of the crystal fiber exiting the molten zone or less, or more particularly about 5% larger or less, or yet more particularly about 2% larger or less. In some embodiments, however, the upper guide tube 510 may have a substantially larger interior diameter than the lower guide tube, such as a diameter up to 1 mm, and thus other components of the upper fiber guide may provide additional horizontal stabilization to the growing crystal fiber.

For example, additional horizontal stabilization as the crystal fiber is pulled upward by upper fiber guide 500 may be provided by a set of guide pads of the upper fiber guide 500 such as the pair of guide pads 520. The guide pads 520 may be compressible and/or elastic and configured to exert a slight horizontal force/pressure on the crystal fiber so as to locate the fiber in the horizontal dimensions and/or to further stabilize its horizontal location as it is pulled away from the molten zone. Thus, the guide pads 520 may apply slight force/pressure to the fiber to precisely locate it, but not so much pressure as to create substantial frictional force which would hinder the fiber's vertical motion as it is pulled upwards. To achieve the right balance between these considerations, the guide pads may be made from a foam or other suitable compressible material and coated with a smooth low-friction material, such as a thin layer of polymeric material, and one which also does not adhere substantially to the fiber as it is pulled. In some embodiments, the pressure applied to the fiber by the guide pads may be adjustable by a guide pad orienting device that may horizontally translate one pad toward the other, or both pads towards each other. The orienting device may employ a screw, spring-loading, or some other suitable pressure producing mechanism to achieve the foregoing.

In the embodiment schematically illustrated in FIG. 5, the actual pulling force is generated by the rotation of spooling drum 530 which is configured to pull the crystal fiber 350 through the guide pads 520 and away from the molten zone by rotating. As shown in the figure, the spooling drum 530 is located such that a vertical vector tangent to its surface—i.e., tangent at the point on the drum which first contacts the crystal fiber 350 as it is spooled—is vertically aligned with the upper fiber guide 510 (again, as shown in the figure). As stated, the spooling drum provides the vertical pulling force, and it also, for sufficiently thin and flexible fibers, may wrap/wind the fiber around its body for compact fiber storage during processing. In other cases—where the fiber 350 is not sufficiently thin and flexible—the end of the fiber may be attached (by some mechanism, e.g., glued) to another thin flexible material (e.g., a line and/or string, etc., not shown in FIG. 5) which is then directly pulled by the spooling drum and wrapped/wound around it—in order to provide vertical pulling force on the fiber as it is formed but without damaging the fiber (by forcing it to bend to the circumference of the spooling drum).

While lower feed guide 400 and upper fiber guide 500 precisely locate the growing crystal fiber horizontally within the LHPG apparatus, it is also important in LHPG operations to have a stable and uniform source of optical energy for heating and melting the source material within the molten zone 310. As detailed in FIG. 6, in some embodiments, an optical energy source 600 may include a laser source 610, various flat turning mirrors 621 and 622, an attenuator 630, a beam expander 640, a reflaxicon 650, an elliptical turning mirror 660, and a parabolic focusing mirror 670. The optical path from laser source 610, through these various optical components, and ultimately to the molten zone 310 is schematically indicated in FIG. 6 (as also shown scaled-down in FIG. 2).

As shown in FIG. 6, a coherent light beam leaves laser source 610, is directed by the turning mirrors 621 and 622 through attenuator 630 to reduce the beam's intensity to a suitable level, and then into beam expander 640. Having been thus initially radially expanded, the increased diameter beam then impinges upon reflaxicon 650 which radially expands the beam further but leaves a gap in the center—i.e., it forms a ring-shaped beam still axially symmetric along its axis of propagation. Note that a cross-sectional view of reflaxicon 650 is depicted in FIG. 6, and so it appears schematically as three disjoint pieces, though it should be understood, of course, that reflaxicon 650 is an optical device with two annular and concentric reflective surfaces which work to produce the expanded ring-shaped beam just described. At this point, the ring-shaped beam is still propagating horizontally, but the next element along the optical path is elliptical turning mirror 660 (again shown in cross-section, but it should be understood that it represents one reflective surface) which redirects the horizontal ring-shaped beam to propagate vertically with the center axis of the now vertical ring-shaped beam roughly aligning with the axes of the upper and lower guides and growing crystal fiber. Thus, at this point, the beam is propagating parallel to the fiber in a ring around it, but not yet contacting it. A parabolic focusing mirror 670 (again shown in cross-section as two pieces in FIG. 6, but this depiction should be understood to represent a singular annular-shaped reflective surface), focuses the beam symmetrically down upon the molten zone 310 to create a spatial region of roughly uniform optical radiation intensity, and of sufficient optical radiation intensity to cause the heating and melting of a fiber crystal source material (whether it be raw polycrystalline source material or a crystal fiber material formed in a prior operation (e.g., a prior LHPG operation)).

As indicated above, the disclosed crystal fiber growing apparatuses (and associated methods) may employ a closed-loop diameter-control feedback circuit/system which operates by substantially continuously measuring (and/or at particular discrete intervals measuring) the diameter of the crystal fiber as it is produced and automatically making process adjustments accordingly, so as to keep the diameter of the growing crystal fiber approximately constant/uniform. Thus, referring again to FIG. 4, in some embodiments, a closed-loop diameter-control feedback system may include a fiber diameter measurement module 460 configured to measure the diameter of growing crystal fiber 350, and a controller 470 configured to adjust the translation rate at which the lower feed guide 400 pushes the source material 340 in response to signals received from the fiber diameter measurement module 460 (as schematically indicated in the figure by signal line 461 connecting measurement module 460 with controller 470). Note that it is the growing crystal fiber 350 whose diameter is measured for purposes of determining the appropriate adjustment to the rate at which the source material 340 is pushed by the lower feed guide 400 (see the double zigzag lines in FIG. 4 schematically indicating a break between the source material 340 pushed by the lower feed guide 400 and the growing crystal fiber 350 having crystalized post-optical heating operation). In this particular embodiment, controller 470 sends a signal to feed belt 440 adjusting the translation rate at which the source material is pushed (as indicated by signal line 471 connecting the two in FIG. 4).

While in principle any technique for measuring fiber diameter may be employed, it has been found particularly effective to monitor a growing crystal fiber's diffraction pattern when irradiated/struck with laser radiation in order to determine the approximate diameter of particular fiber segments as they are produced. Accordingly, as shown in FIG. 4, in some embodiments, a fiber diameter measurement module 460 may include a probe laser 462 (e.g., a red He—Ne laser) and a light detector 464 (e.g., CCD line camera and possibly a data processing unit), with the probe laser configured to irradiate the growing crystal fiber 350 with laser radiation 463, and the light detector 464 configured to measure one or more interference fringes (or series of interference infringes) produced by the interaction of said laser radiation 463 with the growing crystal fiber. Data analysis software (or hardware, depending on the embodiment) associated with the diameter-control feedback system (it may physically reside within the fiber diameter measurement module, the controller of the feedback system, or elsewhere, depending on the embodiment) then interprets the measured interference fringes, and from them calculates an approximate fiber diameter through the evaluation of various formulae relating a fiber's diameter to its interference pattern as described in detail in L. S. Watkins, “Scattering from side-illuminated clad glass fibers for determination of fiber parameters,” Journal of the Optical Society of America 64, 767 (1974); and M. M. Fejer, G. A. Magel, and R. L. Byer, “High-speed high-resolution fiber diameter variation measurement system,” Applied Optics 24, 2362 (1985); each of which is hereby incorporated by reference in its entirety for all purposes. In some instances, the distance between and/or the number of peaks in a series of interference fringes may be used to estimate the fiber diameter, or the shift of peaks in the series of fringes with time may be monitored to gauge changes in the crystal fiber's diameter, or some combination of the foregoing (or even some combination of any of the foregoing metrics in conjunction with other possible techniques for measuring fiber diameter).

Once determined, the approximate fiber diameter may be used by the feedback system's control software (or hardware, depending on the embodiment) to adjust the feed rate (e.g., push rate employed by lower feed guide 400 as detailed herein) in order to appropriately compensate for any calculated changes/fluctuations in fiber diameter. Again, while in principle the pull rate employed by upper fiber guide 500 (as detailed herein) could also be used to compensate for diameter fluctuations (or pull rate in conjunction with push rate), in practice it has been found that adjustment of push rate alone is more effective.

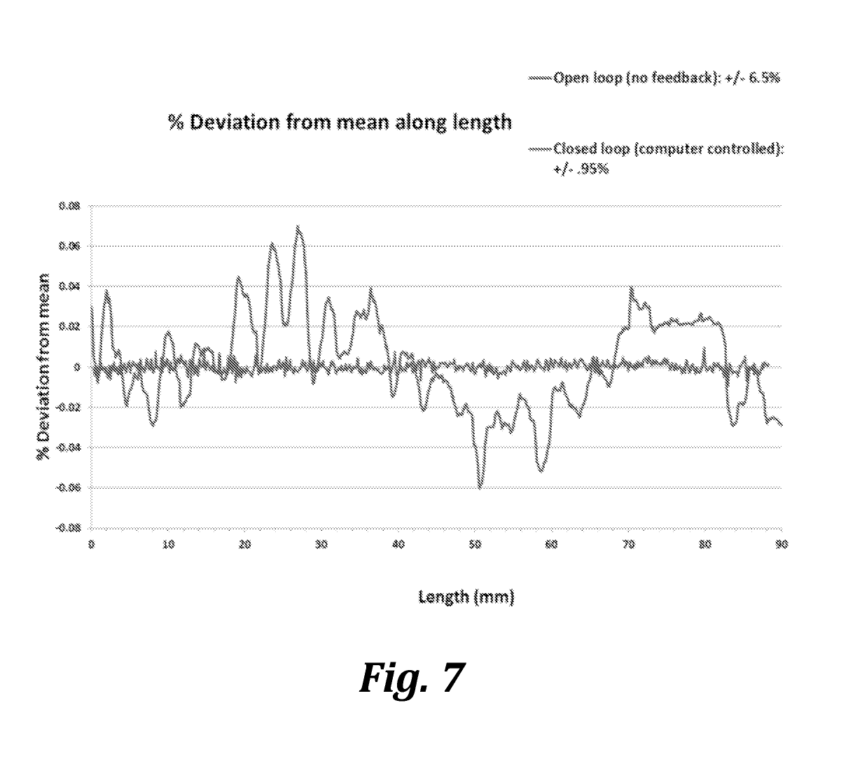

FIG. 7 displays a comparison of lengthwise variations in diameter for a crystal fiber grown using the foregoing closed-loop diameter-control feedback circuit, versus a crystal fiber grown in open-loop mode (i.e., with the diameter-control feedback system disengaged). It was observed that in open loop mode, diameter fluctuations occur on the order of about 7% of total fiber diameter—generally, a result of changes in the source material's diameter, and/or fluctuations in laser power, and/or potentially other environmental factors. In contrast, with the closed-loop diameter control feedback circuit engaged, despite these inevitably varying conditions, diameter fluctuations are reduced to about 1%. It is also noted that, in some embodiments, the extent to which the control software is allowed to intervene during fiber growth may be preset by a variable control circuit proportional gain setting. The proportional gain setting determines how sensitive the control circuit is in responding to changes that are detected (how much of a correction factor to employ). Such a control circuit may also be tailored with an adjustable maxV parameter which works as an upper bound on the actual amount the control circuit is allowed to change the push rate (or, in some embodiments, the pull rate, or both the push and pull rates) at a given time interval, if the control circuit makes a determination it is appropriate to do so. For the plot shown in FIG. 7, the closed-loop diameter-controlled result corresponds to a fiber having been grown with the proportional gain set to 10 and the maxV set to 20%.

### OTHER EMBODIMENTS

Although the foregoing disclosed techniques, operations, processes, methods, systems, apparatuses, tools, films, chemistries, and compositions have been described in detail within the context of specific embodiments for the purpose of promoting clarity and understanding, it will be apparent to one of ordinary skill in the art that there are many alternative ways of implementing foregoing embodiments which are within the spirit and scope of this disclosure. Accordingly, the embodiments described herein are to be viewed as illustrative of the disclosed inventive concepts rather than restrictively, and are not to be used as an impermissible basis for unduly limiting the scope of any claims eventually directed to the subject matter of this disclosure.

1. An apparatus for growing a thin crystal fiber via optical heating, the apparatus comprising:
a source of optical energy for heating a source material to form a molten zone of melted source material;
an upper fiber guide for pulling a growing crystal fiber along a defined translational axis away from the molten zone and thereby also withdrawing un-crystalline melted source material connected with the crystal fiber away from the molten zone so that melted source material may cool, crystalize, and add to the growing crystal fiber; and
a lower feed guide for pushing additional source material along a defined translational axis towards the molten zone;
wherein the lower feed guide's translational axis and upper fiber guide's translational axis are substantially aligned vertically and axially so as to horizontally locate the source material in the path of optical energy emitted from the optical energy source.

2. The apparatus of claim 1, wherein the source material is horizontally located in the path of optical energy within a horizontal tolerance of about 5 μm.

3. The apparatus of claim 1, wherein the upper fiber guide is configured to pull the crystal fiber away from the molten zone at a translational rate greater than the translational rate at which the lower feed guide is configured to push the source material towards the molten zone.

4. The apparatus of claim 3, wherein the translational rate at which the upper fiber guide is configured to pull the crystal fiber is between about 4 and 9 times the translational rate at which the lower feed guide is configured to push the source material.

5. The apparatus of claim 1, further comprising:
a diameter-control feedback system comprising:
a fiber diameter measurement module configured to measure the diameter of the growing crystal fiber; and
a controller configured to adjust the translational rate at which the lower feed guide pushes the source material in response to signals received from the fiber diameter measurement system, so as to keep the diameter of the growing crystal fiber approximately constant.

6. The apparatus of claim 5, wherein the fiber diameter measurement module comprises:
a probe laser configured to irradiate the growing crystal fiber with laser radiation; and
a light detector configured to measure one or more interference fringes produced by the interaction of said laser radiation with the growing crystal fiber.

7. The apparatus of claim 1, wherein the lower feed guide comprises:
a lower guide tube having an interior that defines the translational axis along which the lower feed guide pushes source material towards the molten zone.

8. The apparatus of claim 7, wherein the lower guide tube has an interior diameter of about 150 μm or less.

9. The apparatus of claim 7, wherein the lower feed guide further comprises:
a guide block having a groove; and
a feed belt;
wherein the lower feed guide is configured to push source material towards the molten zone by advancing the feed belt which moves the source material against the groove in the guide block and into and through the interior of the lower guide tube.

10. The apparatus of claim 9, wherein the guide block comprises Teflon.

11. The apparatus of claim 1, wherein the upper fiber guide comprises:
an upper guide tube having an interior that defines the translational axis along which the upper fiber guide pulls the growing crystal fiber away from the molten zone.

12. The apparatus of claim 11, wherein the upper guide tube has an interior diameter of about 1 mm or less.

13. The apparatus of claim 11, wherein the upper fiber guide further comprises:
a pair of guide pads configured to exert horizontal pressure on the crystal fiber from two sides so as to further stabilize its horizontal location as it is pulled away from the molten zone; and
a spooling drum configured to pull the crystal fiber through the pair of guide pads and away from the molten zone by rotating.

14. The apparatus of claim 13, wherein the guide pads comprise a compressible material coated with a smooth material.

15. The apparatus of claim 14, wherein the compressible material is foam and the smooth material is a thin layer of polymeric material.

16. The apparatus of claim 13, wherein the spooling drum is configured to pull the crystal fiber by winding the fiber around the body of the drum.

17. The apparatus of claim 13, wherein the spooling drum is configured to pull the crystal fiber by winding a line attached to the crystal fiber around the body of the drum.

18. A method for growing a thin crystal fiber via optical heating, the method comprising:
heating a source material with optical energy to form a molten zone of melted source material;
pulling a growing crystal fiber along a translational axis defined by a fiber guide away from the molten zone, thereby also withdrawing un-crystalline melted source material connected with the crystal fiber away from the molten zone so that the melted source material may cool, crystalize, and add to the growing crystal fiber; and
pushing additional source material along a translational axis defined by a feed guide towards the molten zone;
wherein the translational axis defined by the feed guide and the translational axis defined by the fiber guide are substantially aligned vertically and axially so as to horizontally locate the source material in the path of optical energy within a horizontal tolerance of about 5 μm.

19. The method of claim 18, wherein the crystal fiber is pulled away from the molten zone at a translational rate greater than the translational rate at which the source material is pushed towards the molten zone.

20. The method of claim 19, wherein the translational rate at which the crystal fiber is pulled is between 2 and 25 times the translational rate at which the source material is pushed.

21. The method of claim 18, further comprising:
measuring the diameter of the growing crystal fiber; and
adjusting the translational rate at which the lower feed guide pushes the source material, so as to keep the diameter of the growing crystal fiber approximately constant.

22. The method of claim 18, wherein the source material pushed towards the molten zone is a rod of polycrystalline material.

23. The method of claim 19, wherein the source material is doped polycrystalline YAG.

24. The method of claim 18, wherein the source material pushed towards the molten zone is a crystal fiber grown in a prior operation of optical heating.

25. The method of claim 24, wherein the diameter of the grown crystal fiber is less than the diameter of the source crystal fiber by a factor of between about 1.5 and 5.

26. The method of claim 18, wherein the diameter of the grown crystal fiber is 40 μm or less, and its length is 30 cm or more.

27. The method of claim 18, further comprising varying the ratio of translational pull to translational push by a rate of between about 0.1% and 10% per cm of drawn crystal fiber over some portion of the crystal fiber's length as it is grown.

28. A crystal fiber grown by a laser heating operation having a diameter of 40 μm or less, and a length of 30 cm or more.

29. The crystal fiber of claim 28 comprising doped crystalline YAG.
